(19) United States
(12) Patent Application Publication
(10) Pub. No.: US 2010/0327421 A1
(43) Pub. Date: Dec. 30, 2010

(54) IC PACKAGE DESIGN WITH STRESS RELIEF FEATURE

(75) Inventor: Jing-En Luan, Singapore (SG)

Correspondence Address: STMICROELECTRONICS, INC., MAIL STATION 2346, 1310 ELECTRONICS DRIVE, CARROLLTON, TX, 75006, US

(73) Assignee: STMICROELECTRONICS ASIA PACIFIC PTE. LTD., Singapore (SG)

(21) Appl. No.: 12/495,515

(22) Filed: Jun. 30, 2009

(51) Int. Cl. H01L 23/31; H01L 21/56

(52) U.S. Cl. 257/687; 438/126; 257/701; 257/E23.124; 257/E21.505; 257/E21.504

(57) ABSTRACT

A protective structure is provided on a substrate to which a semiconductor die is attached. The protective structure surrounds the die and reduces the thermo-mechanical stresses to which the die is subject. The die is protected against cracking, warping, and delamination.

### BACKGROUND

1. Technical Field

The present application relates to the packaging of a semiconductor die and more particularly to the protection of a semiconductor die within a package.

2. Description of the Related Art

Integrated circuits are formed on wafers of semiconductor material. On a typical semiconductor wafer, many identical integrated circuits are formed. The wafer is then diced or cut into many dice, each die comprising an integrated circuit.

The die is usually then packaged both to protect it from physical damage and to place it in a form which can be easily installed in a system of which it will be a part. FIG. 1 illustrates a side view of a typical packaged integrated circuit. The package 20 comprises a substrate 22 and a semiconductor die 24 bonded to a top surface 26 of the substrate 22 by an adhesive layer 28. Wires 30 are coupled by a wire bonding process and electrically connect the die 24 to pads (not shown) of the substrate 22. Plated through holes or other structures electrically couple the wires 30 to ball grid arrays or other structures. Molding compound 32 covers the die 12 and protects it from outside elements. A heat sink may also be provided in the package. FIG. 2 illustrates another typical semiconductor package 20. The die is mounted on lead frame 21 and wires 30 are bonded to the die 24. The die and lead frame are encapsulated in a molding compound 32. In this case, the wires 30 are connected to leads 33 which protrude from the package 20.

For both types of packages, while the packaging protects the die 24 from many kinds of damage, the packaging subjects the die 24 to other risks. The package 20 goes through many cycles of heating and cooling throughout its lifetime. The molding compound 32 typically must be in a liquid state when it is first applied and thus it must be at a temperature above its melting point. The liquid molding compound covers the die 24 and the substrate 22 heating both the die 24 and the substrate 22. The molding compound 32 then is cooled and becomes a solid bonded to both the die 24 and the substrate 22. The integrated circuit is now packaged into a final semiconductor product. At this point the semiconductor product may be subject to testing during which the package 20 heats up, then cools, after which it is further tested to ensure that the integrated circuit is functional and that the package 20 is intact. Thus before the integrated circuit is ever sold it is already subjected to one or more heating/cooling cycles. In some testing, the semiconductor products are subjected to a burn-in cycle in which the packages are heating and cooled from external sources for many cycles, during which time they are tested for operation.

When the die 24 is in its operating environment, it is subjected to many cycles of heating and cooling. Each time the integrated circuit is turned on and in use the die 24 may become very hot. The heating of the die 24 causes the substrate 22 and the molding compound 32 to become hot as well. When the integrated circuit turns off, the die 24, the substrate 22, and the molding compound 32 cool once again. The package 20 may also become hot or cool based on the physical environment in which it is placed.

It is desired to have a package structure for holding the die which will have a long operational life and not degrade or break due to repeated heating and cooling cycles.

### BRIEF SUMMARY

One embodiment provides a stress relief structure on the substrate adjacent to the die. During expansion and compression of the molding compound and the substrate, the stress relief structure functions to reduce the amount of stress felt by the die. The stress relief structure may be in the form of a wall surrounding the die. Both the die and stress relief structure are covered by a molding compound.

In one embodiment the die has a first coefficient of thermal expansion. The stress relief structure has a second coefficient of thermal expansion greater than the first coefficient of thermal expansion. The molding compound has a third coefficient of thermal expansion greater than the second coefficient of thermal expansion.

In one embodiment the stress relief structure is a protective ring attached to the substrate and laterally surrounding the die.

In a further embodiment the stress relief structure comprises a plurality of stress relief posts spaced along a perimeter of the die.

In one embodiment the stress relief structure is attached to the substrate by an adhesive film.

In one embodiment the stress relief feature is of a different material than the substrate.

In one embodiment the stress relief structure is formed from the substrate by selectively etching the substrate to leave elevated portions thereof relative to the surface to which the die will be attached.

One embodiment is a method for forming an integrated circuit package with a stress relief structure. A semiconductor die is attached to a surface of a substrate. The stress relief structure is attached to the surface of the substrate adjacent to the die. The molding compound then covers the die and the stress relief structure.

### BRIEF DESCRIPTION OF THE SEVERAL VIEWS OF THE DRAWINGS

FIG. 1 shows a cross-section of a known integrated circuit package.

FIG. 2 shows a cross-section of another known integrated circuit package.

FIG. 3A-3D show cross-section views of an integrated circuit package at various stages of manufacture according to principles of the present invention.

FIG. 4 shows a top view of an embodiment of an integrated circuit package with a stress relief structure according to principles of the present invention.

FIG. 5 shows a top view of an embodiment of an integrated circuit package with a stress relief structure according to principles of the present invention.

FIG. 6 shows a top view of an embodiment of an integrated circuit package with a stress relief structure according to principles of the present invention.

FIG. 7 shows a top view of an embodiment of an integrated circuit package with a stress relief structure according to principles of the present invention.

FIG. 8 shows a top view an embodiment of an integrated circuit package with a stress relief structure according to principles of the present invention.

FIGS. 9A and 9B show a top and side views of an embodiment of an integrated circuit package with a stress relief structure according to principles of the present invention.

FIGS. 10A-10D show cross-section views of an integrated circuit package at various stages of manufacture according to principles of the present invention.

FIG. 11 shows a cross-section view of a package according to one embodiment according to principles of the present invention.

FIG. 12 shows a top view of an embodiment of an integrated circuit package with a stress relief structure according to principles of the present invention.

FIG. 13 shows a top view of an embodiment of an integrated circuit package with a stress relief structure according to principles of the present invention.

### DETAILED DESCRIPTION

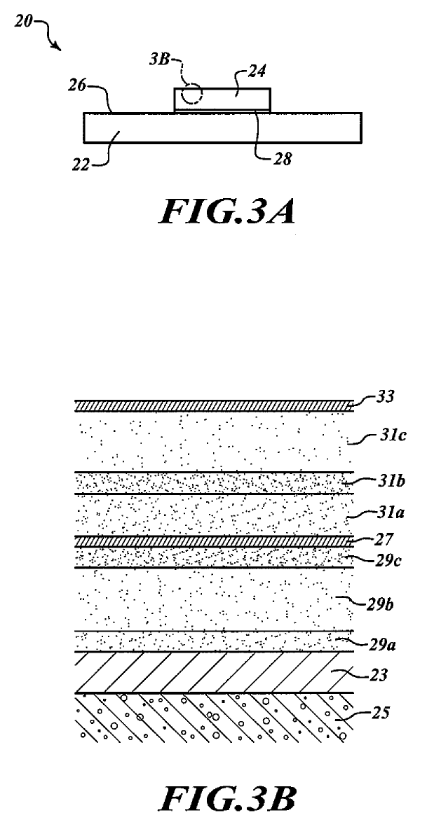

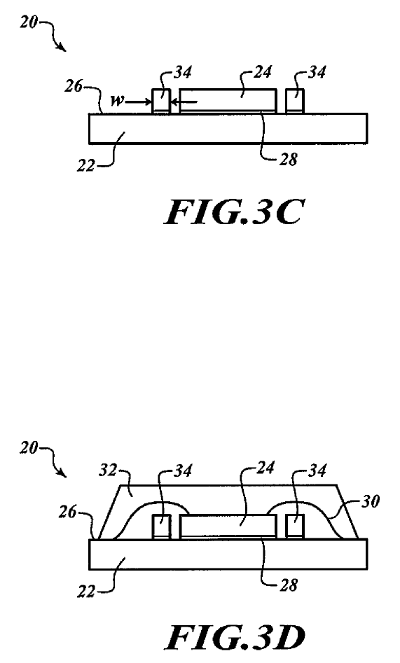

FIG. 3A illustrates an integrated circuit package 20 in an intermediate stage of manufacture according to one embodiment. Semiconductor die 24 is attached to a top surface 26 of a substrate 22 by means of an adhesive film 28 as previously described.

Recent integrated circuits have used different materials for the integrated circuit construction than previously used. For many years, standard silicon dioxide, silicon nitride, and polysilicon layers were used to construct various interconnection layers between the substrate and the operational transistors that formed the integrated circuit. Initial circuits made some years ago had one or two layers of polysilicon on top of which may be one or two layers of metal. Recent advances in semiconductor technology have drastically increased the complexity of integrated circuits. Many circuits may have between two and five layers of polysilicon and between seven and twelve layers of metal above the polysilicon layers. Further, the size of the minimum gate width of transistors has shrunk dramatically with transistors in the range of 65 nm, 45 nm, and 32 nm becoming common. Future transistor sizes may approach 20 or 18 nm for the gate length.

Another improvement further increasing the complexity is the use of many different types of dielectric layers between the substrate and the first metal layer and between various metal layers.

FIG. 3B illustrates an enlarged view of a portion of FIG. 3A as one example of the increased complexity of the layers and the dielectric materials used between layers. As illustrated in FIG. 3B, the uppermost polysilicon layer 23 will have positioned below it a plurality of insulating layers 25, which will include various nitride and oxide layers as well as a plurality of additionally polysilicon layers separated from each other by various sublayers of silicon nitride, silicon dioxide, and other types of insulators. Above the last polysilicon layer 23 is a first metal layer 27 having a premetal dielectric layer 29 composed of a plurality of sublayers 29a, 29b, and 29c between the polysilicon layer 23 and the first metal layer 27. In small geometry silicon chips, such as 90 nm and smaller, the premetal dielectrics are usually made of a low-k material. This low-k material may be an aerogel, a nanoporous dielectric, or other extremely low-k dielectric material. Above the first metal layer 27 will be another low-k dielectric layer 31 composed of a plurality of low-k dielectric layers 31a, 31b, and 31c on top of which is yet another metal layer 33. This continues for many layers and sublayers.

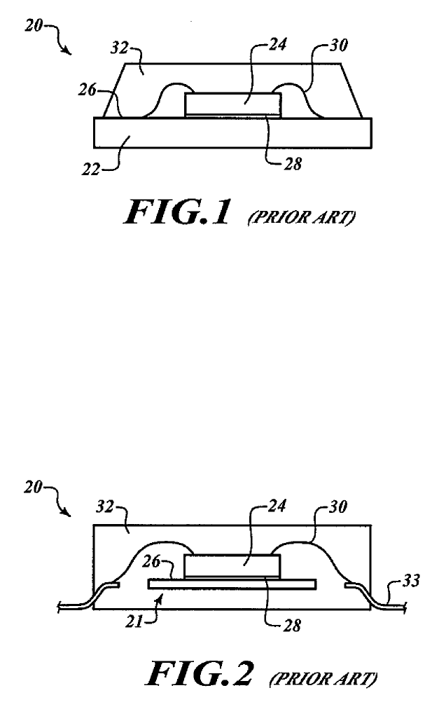

In the prior art, as explained in FIGS. 1 and 2, the dielectric layers between the various metal layers were usually composed of one or perhaps two glass layers, such as a spin-on glass, a silicon dioxide glass, or other strong layers which had high adhesive properties, and bonded strongly to each other. On the other hand, the more modern chips, as shown in the embodiment of FIGS. 3A and 3B frequently use dielectric materials which have numerous small pockets of air distributed throughout in order to reduce the dielectric constant. Such low-k dielectric materials are not as structurally strong as a more solid glass, such as a spin-on glass or a solid silicon dioxide glass. In addition, these layers often contain chemical compositions which do not stick as tightly to each other as the prior art glasses. Such dielectric compounds may contain various combinations of carbon, fluoride, hydrogen, and other elements to increase the porosity and reduce the dielectric constant. Through various tests and measurements, the present inventor has realized that, while such low-k dielectrics provide enhanced electrical performance, the structural integrity is substantially less than was provided in prior art semiconductor devices. In addition, the adhesive bonding strength between the various layers is reduced.

While FIG. 3B shows only one polysilicon layer and two metal layers, modern chips will have numerous layers of each, with each having between two and five sublayers of dielectric material in between them, each sublayer constructed of slightly different chemical compositions from each other.

The present inventor has subjected such low-k dielectric circuits to a number of tests to more fully determine the structural integrity over long-term operation.

Repeated cycles of heating and cooling were found to be very problematic to the structural integrity of integrated circuits with many low-k dielectric layers. When the die is heated or cooled, it expands or shrinks according to a coefficient of thermal expansion (CTE) particular to the material of the die. Each dielectric layer may have a slightly different CTE coefficient of expansion during heating. A material with a high CTE will expand or shrink more than a material with a lower CTE under a given increase or decrease in temperature. When the package 20 is heated or cooled, the molding compound 32, the die 24, and the substrate 22 and each of the layers 23, 25, 27, 29, and 31, and sublayers expand or contract differently from each other. This disparity in expansion causes the die 24 to experience compressive, expansive, and tensile forces. The stress is felt more intensely at the edges and corners of the die 24. The repeated cycles of expansion and contraction may eventually cause layers 29 and 31 to crack. If a crack propagates through the die 24 to the integrated circuitry of the die 24, the crack in the die 24 can be fatal to the functionality of the integrated circuit.

The repeated stresses may also cause delamination of the layers 29 and 31 or other components of the package 20. Delamination is the separation or unbending of any of the layers, sublayers, or components of the die 24. For example, under stress, the adhesion between the various layers in die 24 may fail. Delamination between any of the components can damage functionality of the integrated circuit.

The stresses also cause warping of the die 24. The stress of the expansion and contraction of the components of the package 20 can cause curvature of the die 24. This curvature, which is focused at the edges and corners of the die 24, can result in poor solder joint formation in certain kinds of packages. Furthermore, the curvature can result in a loss of functionality of the integrated circuit.

In applications where a small dielectric constant is needed (low k applications), a porous silicon is often used as a dielectric between circuit components and layers of the integrated circuit. The porous silicon is particularly prone to fracturing under stress. Any warping of the die 24 can cause fracturing of the porous silicon. Compressive forces of contraction and expansion may also cause the porous silicon to fracture. This fracturing can damage functionality of the integrated circuit.

The effects of thermo-mechanical stress are greater with larger die size. With system on chip (SOC) technology, die sizes increase due to the number of systems being integrated into one integrated circuit. Stress at the corners and edges of a larger die cause greater torque on the die and can more easily cause cracking, warping, or delamination of the die. The present invention is designed to prevent these problems in the large dies having low-k dielectrics.

In FIG. 3C a stress relief structure 34 is attached to the top surface 26 of the substrate 24 by means of an adhesive film 36.

In one embodiment, the stress relief structure 34 is approximately the same height as the semiconductor die 24. In a second embodiment, it is about 10% taller than the die. Having the stress relief structure 10% to 20% taller than the die is beneficial in some embodiments for providing increased protection. If the die is of a larger size, then having stress relief structure 24 at least 10% taller than the die is preferred. For example, if the die is in excess of 100 mm², then having the stress relief structure 10% or more taller than the die provides additional protection. It has a width “w” that can be based on the package dimensions, the size of the die or other design choices. A width w of 0.5 to 2 mm is acceptable. The stress relief structure 34 is placed as close to the die 24 as possible without contacting or electrically interfering with the die 24. In one embodiment, the stress relief structure is between 10 and 100 microns from the die, with 30-50 microns being preferred. In another embodiment the stress relief structure is 20 microns from the die. For some dies and packing, a spacing of from 100 to 800 microns is acceptable

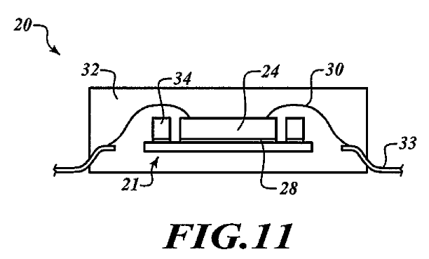

In this embodiment of FIGS. 3A-3D the substrate 22 is shown as a PC board or as a heat sink, and is thus quite thick as the molding compound 32 is on top of the substrate 22. In other embodiments, the substrate 22 is a lead frame 21 of the standard type, examples of which are shown in FIGS. 11-13. In such a design, the substrate of the lead frame 21 is enclosed on all sides by the molding compound 34, as is well known in the standard lead frame design.

FIG. 3D shows the package 20 of FIG. 3B after the wires 30 have been formed via wire bonding and the molding compound 32 has been applied. As previously described, the expanding and shrinking of the molding compound 32, coupled with the expanding and shrinking of the substrate 22, during heating and cooling cycles can cause great stress to the die 24. This stress can cause cracks to form in the die 24 which can destroy functionality of the integrated circuit. Also, the stress can cause delamination of the substrate 22 from the die 24, the substrate from the molding compound 32, or the molding compound 32 from the die 24. The stress on the die 24 can also cause the die 24 to warp.

The bond wires 30 preferably arch over and do not contact the stress relief structure 34, as shown in FIG. 3D. In those embodiments in which the stress relief structure 34 is an insulator, such as a ceramic or silicon, it is acceptable for the lead wires 30 to brush against or to lie on it, but if a conductive material, such as doped silicon or metal is used, then care must be taken when attaching the lead wires to not contact the stress relief structure 34. An electrical insulator is preferred in some embodiments for this reason. The stress relief structure 34 aids in relieving the stress on the die 24. The presence of the stress relief structure 34 absorbs much of the compressive stress from the die 24. The integrated circuitry within the die is typically located near the surface of the die 24 opposite the substrate 22. The presence of the stress relief structure helps to absorb much of the force which compresses presses or pulls on the die due to the shrinking or expanding of the molding compound. These compressive forces are particularly acute at the edges and corners of the die. The stress relief structure 34 greatly reduces these stresses and thereby protects the functionality of the integrated circuit within the die 24. The stress relief structure 34 may reduce stress on the die 24 both from expansion and contraction of the molding compound 32. Under either contraction or expansion of the molding compound 34, the stress relief structure 24 may reduce the amount of stress felt by the die 24.

The compression and expansion of the molding compound 32, the substrate 22, and the die 24 also can place great tensile stress on the die 24. One source of this tensile stress is the mismatch in expansion/compression between the die 24 and the substrate 22. As the substrate typically tends to expand more than the die, the adhesion of the die to substrate 22 causes the substrate to bend upwards at the corner. When the package is cooled, the substrate tends to contract more than the die and the adhesion between the de 24 and the substrate 22 tends to bend the corners of the substrate 22 downward relative to the die 24. In either case this bending causes tensile stress on the die 24 and tends to cause bending of the die 24, delamination of the various layers in die 24 or from the substrate 22, or cracking of the die. Any of these problems can cause a loss in functionality of the integrated circuit. The presence of the stress relief structure 34 inhibits this bending and this reduces the amount of stress felt by the die. The stress relief feature can thus help to relieve the die 34 from tensile forces, compressive forces, and expansive forces.

In one embodiment, the stress relief structure 34 is made of a material having a coefficient of thermal expansion (CTE) which is greater than a CTE of the die 24 and lower than a CTE of the molding compound 32. In this configuration, the stress relief structure 34 particularly helps to relieve stress from the die 24 from both compression and expansion of the molding compound 32. During compression of the molding compound 32, the stress relief structure 34 relieves much of the stress on the die 24 by contracting less than the molding compound 32 but more than the die 24. During expansion of the molding compound 32, the stress relief structure 34 relieves much of the stress on the die 24 by expanding less than molding compound 32 but more than the die 24.

In one embodiment the stress relief structure 34 has a CTE which is lower than the CTE of the substrate 22. It may also be beneficial for the stress relief structure 34 to have a CTE which is identical to that of the substrate 22. Accordingly, the stress relief structure may be made either of the same material as the substrate 22 or from a material different than that of the substrate 22. The substrate may be, for example, an organic substrate, a printed circuit board, a metal lead frame, a heat sink, or any other suitable substrate.

Materials for the stress relief structure include ceramic, silicon, alloy 42, or any other suitable material that will protect and relieve stress on the die. Of course there are many other suitable materials which will be apparent to those of skill in the art based on the description provided herein.

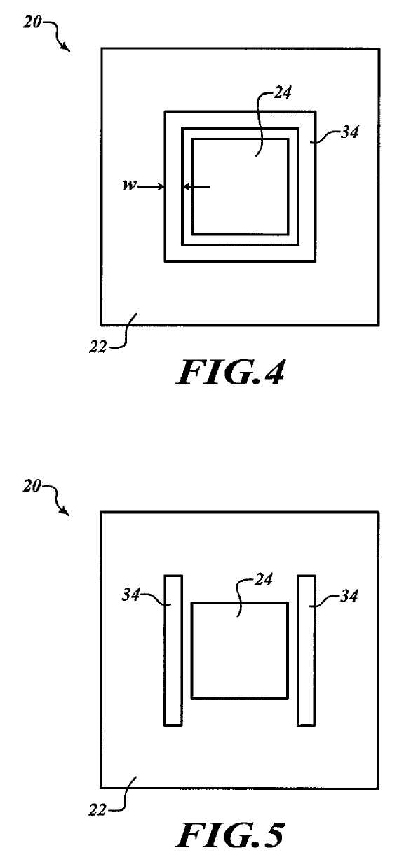

FIG. 4 shows a top view of an integrated circuit package 20 with a stress relief structure 34 according to one embodiment. For clarity, the molding compound 32 and the wires 30 are not shown. In FIG. 4, the stress relief structure 34 is in the form of protective ring which laterally surrounds the die 24. The stress relief structure 34 is adjacent to the die 24 and in this configuration provides stress relief to the die 24 during cycles of heating and cooling as described above. The ring is preferably a rectangle that is the exact shape of the perimeter of the die. It may be a square ring or an oblong ring, and is positioned closely adjacent the sides of the die on all sides.

FIG. 5 shows a top view illustrating one embodiment of the stress relief structure 34. In this embodiment the stress relief structure 34 is in two portions extending along two sides of the die 24. This configuration requires less material for the stress relief structure 34 while still providing some protection to the die 24.

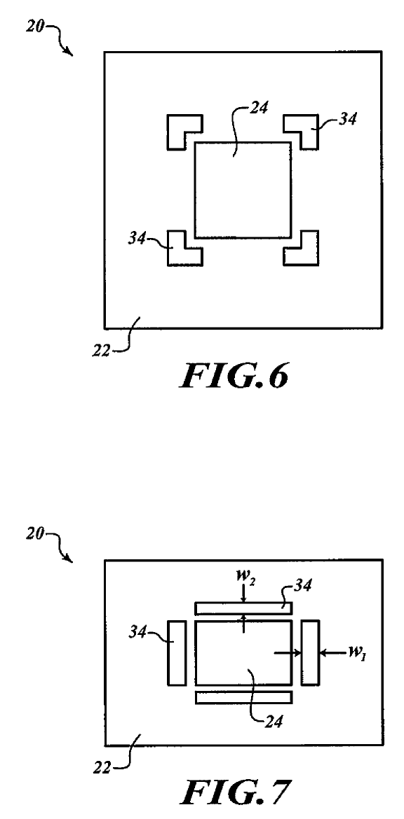

FIG. 6 shows a top view illustrating an embodiment in which the stress relief structure 34 is in 4 smaller portions at the four corners of the die 24. Stresses due to heating/cooing are felt more acutely at the corners of the die 24. In this configuration, the die 24 may be protected from stress while using minimal material to from the stress relief structure 34.

FIG. 7 shows a top view illustrating an embodiment in which the stress relief structure 34 is in the form of four portions extending along the four sides of the die 24. The embodiment of FIG. 7 allows for the stress relief structure to be manufactured in a series strips which can then be attached to the substrate 22. In this embodiment, an oblong die 24 is shown as one example, and of course, the die, and corresponding protection structures, may be oblong in all embodiments for FIGS. 3A to 13.

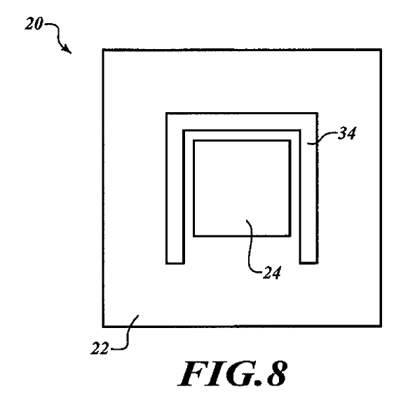

FIG. 8 shows a top view illustrating an embodiment in which the stress relief structure 34 is in the form of a horseshoe surrounding three sides of the die 24.

Preferably, all sides of the stress relief structure have the same width w as shown in FIGS. 3B-4, but in some embodiments, the width may be different, having a first width w₁ on some sides and a second width w₂ on other sides to accommodate differences in die shape or location in a package.

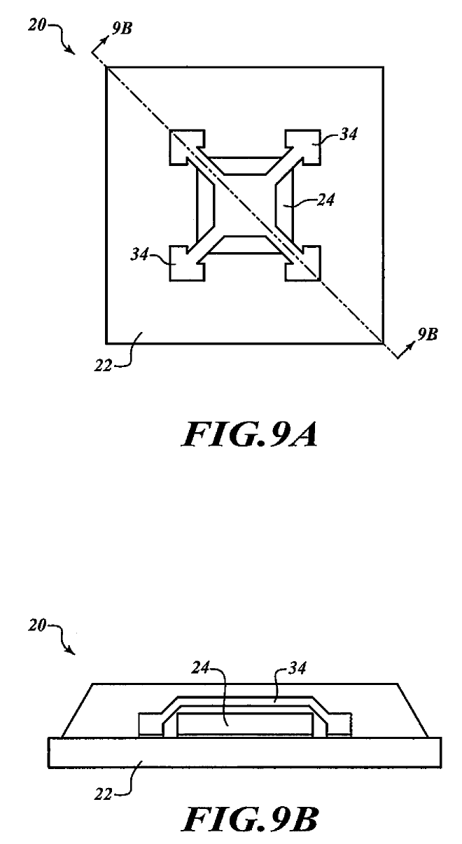

FIGS. 9A and 9B show an embodiment in which the stress relief structure 24 is attached to the substrate 22 at the four corners of the die 24 and overarches the die 24. In this way, the stress relief structure 34 serves both to protect the die 24 from stress and to help dissipate heat from the integrated circuitry within the die 24 near the top surface of the die 24.

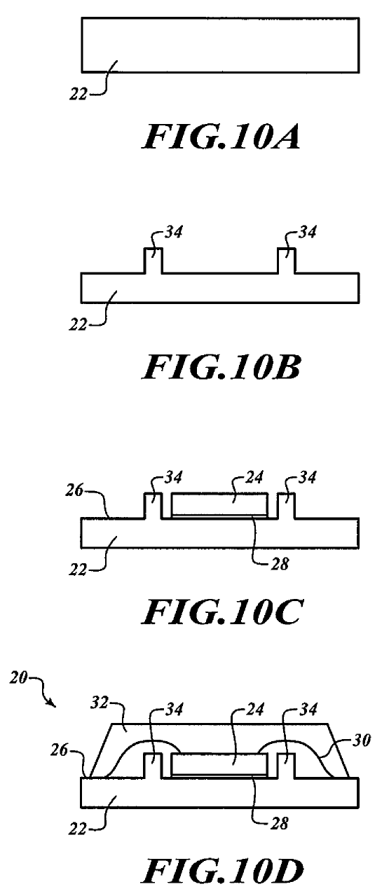

FIGS. 10A-10D illustrate another embodiment in which the stress relief structure 34 is formed from the substrate. FIG. 10A shows a substrate 22 before a die 24 has been attached. To achieve the structure of FIG. 10B, the substrate 22 is selectively etched according to any known method by masking the surface of the substrate 22 in order to leave the stress relief structure 34 after the etch. In this way the stress relief structure 34 may be formed from the substrate 22. The stress relief structure 34 may be in any suitable configuration such as those shown in previous figures by way of example or other suitable configurations which will be apparent to those of skill in the art. All such configurations are within the scope of this disclosure.

In FIG. 10C the die 24 is attached to the substrate 22 by means of the adhesive film 28. FIGS. 10A-10D show an embodiment in which the stress relief structure is first formed, after which the die is positioned adjacent to it. This is different from previous embodiments in which the die 24 was attached before placement of the stress relief structure 34. In FIG. 10D the wires 30 are formed and the molding compound 30 is applied as described previously.

FIG. 11 illustrates an embodiment in which the bonding wires 30 are attached to leads 33 which protrude from the molding compound 32 and a paddle 38 of a lead frame 21 is used for the substrate. The die 24 is attached to the lead frame 21, which is one example of a substrate 22. Stress relief structure 34 is then attached to the lead frame 21 by means of an adhesive. Wires 30 are then formed between the die 24 and the leads 40 by wire bonding. The molding compound 32 is then applied which completely surrounds the die 24 and lead frame 21.

The lead frame paddle 38, sometimes called a die pad, has a dimension as appropriate to hold and support the various embodiments of the stress relief structure 34. For the ring embodiment, the paddle 38 of the lead frame 21 is larger than the die on all sides; for the embodiments of FIGS. 5 and 6, the paddle 38 on which the die rests need only be larger than the die 24 by the amount and in the locations needed to support the selected stress relief structure 34. In some cases, the same shape of lead frame paddle 38 can be used, or, alternatively, a custom shape can be provided.

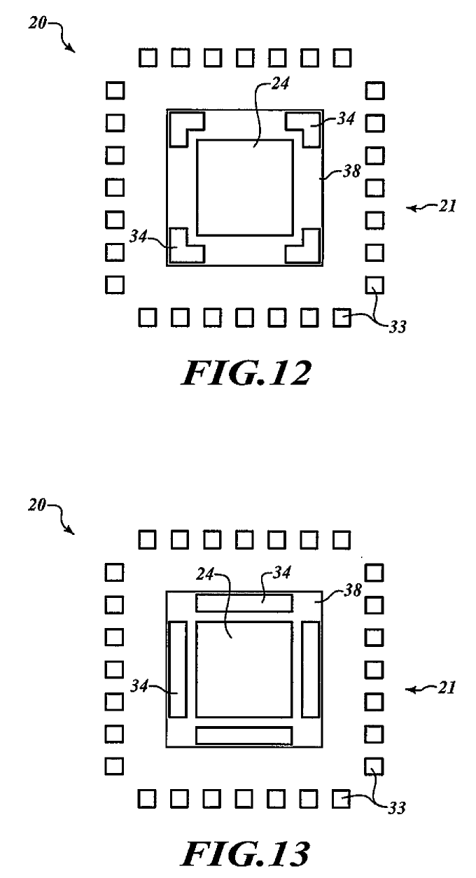

FIG. 12 shows a top view of an embodiment in which the die 24 sits on a paddle 38 of a lead frame 21 and the bonding wires (not shown) are connected to leads 33 for a lead frame 21. The stress relief structure 34 is in a configuration similar to that of FIG. 5 with portions located at the four corners of the die 24 on the substrate 22 of the paddle 38. FIG. 13 shows another embodiment in which the stress relief structure 34 is configured with four portions positioned along the sides of the die 24 similar to FIG. 6 but is mounted on a paddle 38 of a lead frame 21, for the substrate 22.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device comprising:
a substrate;
a semiconductor die on a surface of the substrate, the semiconductor die having a first coefficient of thermal expansion;
a stress relief structure on the surface of the substrate, the stress relief structure being adjacent to the die and having a second coefficient of thermal expansion greater than the first coefficient of thermal expansion; and
a molding compound covering the die and the stress relief structure, the molding compound having a third coefficient of thermal expansion greater than the second coefficient of thermal expansion.

2. The device of claim 1 wherein the stress relief structure laterally surrounds the die.

3. The device of claim 1 wherein the stress relief structure comprises a plurality of protective structures spaced along a perimeter of the semiconductor die.

4. The device of claim 1 wherein the stress relief structure is formed by selectively etching the substrate to leave the stress relief structure elevated above the surface of the substrate.

5. The device of claim 1 wherein the substrate is an organic substrate.

6. The device of claim 1 comprising a first adhesive film between the substrate and the die.

7. The device of claim 1 wherein the stress relief structure is attached to the substrate by a second adhesive film.

8. The device of claim 1 wherein the substrate has a fourth coefficient of thermal expansion greater than the second coefficient of thermal expansion.

9. A method, comprising:
attaching a semiconductor die to a surface of a substrate;
attaching a stress relief structure to the surface of the substrate, the stress relief structure being adjacent to the die; and
covering the die and the stress relief structure with a molding compound.

10. The method of claim 9 wherein the die has a first coefficient of thermal expansion, the stress relief structure has a second coefficient of thermal expansion greater than the first coefficient of thermal expansion, and the molding compound has a third coefficient of thermal expansion greater than the second coefficient of thermal expansion.

11. The method of claim 10 wherein the substrate has a fourth coefficient of thermal expansion greater than the second coefficient of thermal expansion.

12. The method of claim 9 wherein the stress relief structure is formed of one of a ceramic material, silicon, or alloy 42.

13. The method of claim 9 wherein the substrate is an organic substrate.

14. The method of claim 9 wherein the stress relief structure is of a same material as the substrate.

15. A device, comprising:
a substrate of a first material;
a semiconductor die attached to a surface of the substrate;
a stress relief structure on the surface of the substrate adjacent to the die, the stress relief structure being of a second material different from the first material; and
a molding compound covering the die and the stress relief structure.

16. The device of claim 15 wherein:
the die is of a first coefficient of thermal expansion;
the stress relief structure is of a second coefficient of thermal expansion greater than the first coefficient of thermal expansion; and
the molding compound is of a third coefficient of thermal expansion greater than the second coefficient of thermal expansion.

17. The device of claim 16 wherein the substrate is of a fourth coefficient of thermal expansion greater than the third coefficient of thermal expansion.

18. The device of claim 15 wherein the stress relief structure overarches the die.
